(19) United States
(12) Patent Application Publication
(10) Pub. No.: US 2026/0068385 A1
(43) Pub. Date: Mar. 5, 2026

(54) DISPLAY DEVICE

(71) Applicant: LG Display Co., Ltd., Seoul (KR)

(72) Inventors: Tae Yoon KIM, Gyeonggi-do (KR); Bung Goo KIM, Gyeonggi-do (KR); Hyoung Ho AHN, Gyeonggi-do (KR); Hee Won LEE, Gyeonggi-do (KR); Jun Young JO, Gyeonggi-do (KR); Hye Sun JUNG, Gyeonggi-do (KR); Dong Geun BAE, Gyeonggi-do (KR); So Hee KIM, Gyeonggi-do (KR)

(21) Appl. No.: 19/306,819

(22) Filed: Aug. 21, 2025

(30) Foreign Application Priority Data
Aug. 30, 2024 (KR) 10-2024-0117686

(51) Int. Cl. H10H 29/37; H10H 29/855

(52) U.S. Cl. CPC H10H 29/37; H10H 29/8552

(57) ABSTRACT

A display device includes a substrate; a plurality of pixel driving circuits positioned on the substrate; a plurality of insulating layers positioned on the plurality of pixel driving circuits; a plurality of banks positioned on the plurality of insulating layers; a plurality of micro-LEDs positioned on the plurality of banks and respectively electrically connected to the plurality of pixel driving circuits; and a first optical layer positioned to surround the plurality of micro-LEDs and the plurality of banks, wherein the first optical layer may include at least one recess between the plurality of micro-LEDs.

### CROSS-REFERENCE TO RELATED APPLICATION

Pursuant to 35 U.S.C. § 119(a), this application claims the benefit of an earlier filing date and right of priority to Korean Patent Application No. 10-2024-0117686, filed Aug. 30, 2024, the disclosure of which is incorporated herein by reference in its entirety.

### TECHNICAL FIELD

The present specification relates to an LED display device and a method of fabricating the same.

### BACKGROUND

With the recent trend toward larger display devices, there is a growing demand for flat display elements that occupy less space, and the technology of flat panel display devices, such as a liquid crystal display (LCD) device or an organic electroluminescent display device (OLED display device) incorporating organic light emitting diodes (OLEDs), have been rapidly advancing.

### SUMMARY

A display device according to one implementation of the present specification may include: a substrate; a plurality of pixel driving circuits positioned on the substrate; a plurality of insulating layers positioned on the plurality of pixel driving circuits; a plurality of banks positioned on the plurality of insulating layers; a plurality of micro-LEDs positioned on the plurality of banks and respectively electrically connected to the plurality of pixel driving circuits; and a first optical layer positioned to surround the plurality of micro-LEDs and the plurality of banks, wherein the first optical layer may include at least one recess between the plurality of micro-LEDs.

A display device according to another implementation of the present specification may include: a substrate including a display area having a plurality of pixels and a non-display area; a pixel driving circuit positioned on the substrate; a plurality of insulating layers and a plurality of banks positioned on the pixel driving circuit; a plurality of micro-LEDs positioned on the plurality of banks and respectively electrically connected to the plurality of pixel driving circuits; and a first optical layer including a recess surrounding the plurality of micro-LEDs, wherein the recess may at least partially overlap the plurality of banks.

### BRIEF DESCRIPTION OF THE DRAWINGS

The above and other objects, features, and advantages of the present disclosure will become more apparent to those of ordinary skill in the art by describing exemplary implementations thereof in detail with reference to the attached drawings.

FIG. 1 is an exploded perspective view of a display device according to one implementation of the present specification.

FIG. 2 is a plan view of a display device according to one implementation of the present specification.

FIG. 3 is a plan view of a display device according to one implementation of the present specification.

FIG. 4 is an enlarged view of a display device according to one implementation of the present specification.

FIG. 5 is a plan view of a display device according to one implementation of the present specification.

FIG. 6 is a cross-sectional view taken along line A-A′ in FIG. 3.

FIG. 7 is an enlarged view of a light emitting element according to one implementation of the present specification.

FIG. 8 is a plan view of a display device according to one implementation of the present specification.

FIG. 9 is a plan view of a display device according to one implementation of the present specification.

FIG. 10 is a cross-sectional view taken along line B-B′ in FIG. 9.

FIGS. 11A to 11E are process diagrams illustrating a method of fabricating a display device according to one implementation of the present specification.

FIG. 12 is a cross-sectional view taken along line C-C′ in FIG. 9.

FIG. 13 illustrates an example of an electronic device to which a display device according to implementations of the present specification is applied.

### DETAILED DESCRIPTION

In a liquid crystal display device, a backlight unit can be positioned below a liquid crystal panel with a polarizing plate attached to the front and rear surfaces, and in some scenarios, less than 5% of light from a light source provided in the backlight unit passes through the liquid crystal panel, resulting in a disadvantage in terms of light efficiency.

In the case of the organic electroluminescent display device, although the light efficiency is improved compared to the liquid crystal display device, it still has limitations in light efficiency and also disadvantages in terms of durability and/or lifespan of the display device.

Accordingly, in order to overcome the aforementioned problems of the liquid crystal display device and/or the organic electroluminescent display device, a light emitting diode (LED) display device using an LED as a light emitting element have recently been developed. A small-sized LED such as a mini-LED or an ultra-small-sized LED such as a micro-LED may be used in the LED display device.

This LED display device is a display device that can display an image by placing a mini-LED or a micro-LED in each sub-pixel, and has great advantages in terms of low power consumption and miniaturization.

Since such LEDs emit light in a top-emission manner, the emitted light may be mixed with light of different colors emitted from adjacent LEDs, and thus a method for reducing color mixing can be implemented.

Implementations of the present specification can provide an LED display device and a method of fabricating the same, which may reduce color mixing between LEDs in the display device while improving process efficiency without employing additional processes.

According to implementations of the present specification, as the respective LEDs arranged in the display device emit light, color mixing with adjacent LEDs may be reduced, thereby minimizing color interference between the LEDs.

According to implementations of the present specification, in some scenarios since no additional process is added to form the structure of the display device, the processing time and the processing cost may be reduced, thereby improving process efficiency.

The effects of the present specification are not limited to those mentioned above, and other effects that are not explicitly mentioned will be clearly understood by those skilled in the art from the description of the claims.

The advantages and features of the present specification, and methods of achieving them will become apparent upon reference to the implementations described in detail below in conjunction with the accompanying drawings. However, the present specification is not limited to the following implementations disclosed herein, but may be implemented in various different forms; rather, the present implementations are provided to make the disclosure of the present specification complete and to enable those skilled in the art to fully comprehend the scope of the present specification.

The shapes, sizes, proportions, angles, numbers, and the like of elements shown in the drawings to illustrate implementations of the present specification are merely illustrative and are not intended to be limiting. Identical reference numerals may designate identical components throughout the description. Further, in describing the present specification, detailed descriptions of related known technologies may be omitted so as not to obscure the essence of the present specification. Terms such as, “including,” “having,” or “comprising” as used herein are generally intended to allow for the addition of other components, unless the terms are used with the term “only.” References to components of a singular noun include the plural of that noun, unless specifically stated otherwise.

In the interpretation of components, they are construed to include margins of error, even if not explicitly stated.

When describing a positional relationship, for example, “on top of,” “above,” “below,” “next to,” or “adjacent to” describes the positional relationship of two parts, one or more other parts may be located between the two parts, unless “immediately,” “directly,” or “near to” is used.

When describing a temporal relationship, “after,” “following,” “next to,” or “before” describes a temporal antecedent or consequent relationship, which may not be continuous unless “immediately” or “directly” is used.

The first, the second, and so on are used to describe various components, but these components are not limited by these terms. These terms are used only to distinguish one component from another. Therefore, the first component referred to below may be a second component within the technical spirit of the present specification.

Terms such as first, second, A, B, (a), or (b) may be used to describe elements of the present specification. Such terms are intended only to distinguish one component from another and are not intended to define the nature, sequence, order, or number of such components.

When a component is described as being “connected,” “coupled,”, “accessed,” or “attached” to another component, it is to be understood that the component may be directly connected, coupled, accessed, or attached to the other component, but that there may also be other components interposed between the respective components which may be indirectly connected, coupled, accessed, or attached, unless specifically stated otherwise.

When a component is described as being “in contacted” or “overlapped” with another component, it is to be understood that the component may be in direct contacted or overlap with the other component, but that there may also be other components “interposed” between the respective components which may be in direct or indirect contacted or overlap with, unless specifically stated otherwise.

It should be understood that the term “at least one” includes all possible combinations of one or more related components. For example, the meaning of “at least one of the first, second, and third components” may be understood to include not only the first, second, or third component, but also any combination of two or more of the first, second, and third components.

The terms the first direction, the second direction, the third direction, the X-axis direction, the Y-axis direction, and the Z-axis direction are not to be interpreted solely as a geometric relationship in which the relationship to one another is perpendicular, but may refer to a broader range of orientations in which the configurations of the present specification may function.

Each of the features of various implementations of the present specification may be coupled or combined with one another in whole or in part, and may be technologically interlocked and operated in various ways, and each of the implementations may be carried out independently or in conjunction with one another.

Hereinafter, various implementations of the present specification will be described in detail with reference to the accompanying drawings.

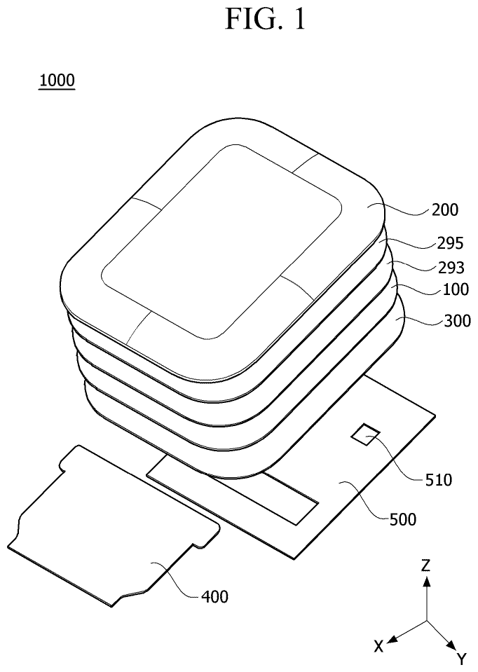

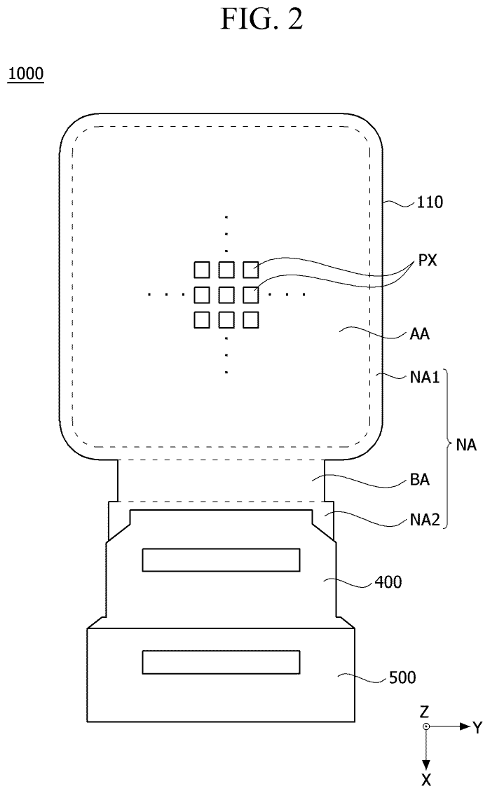

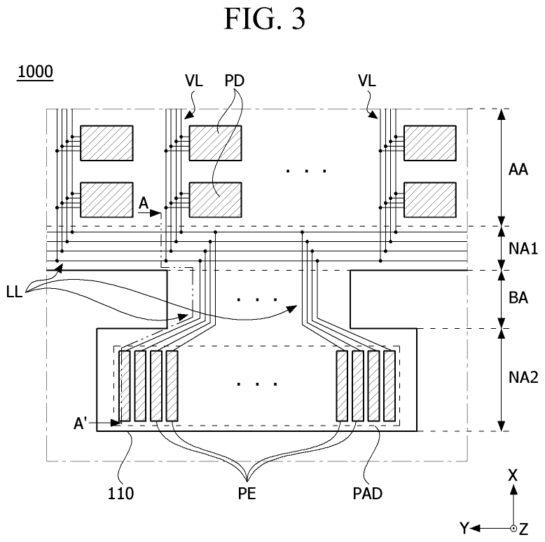

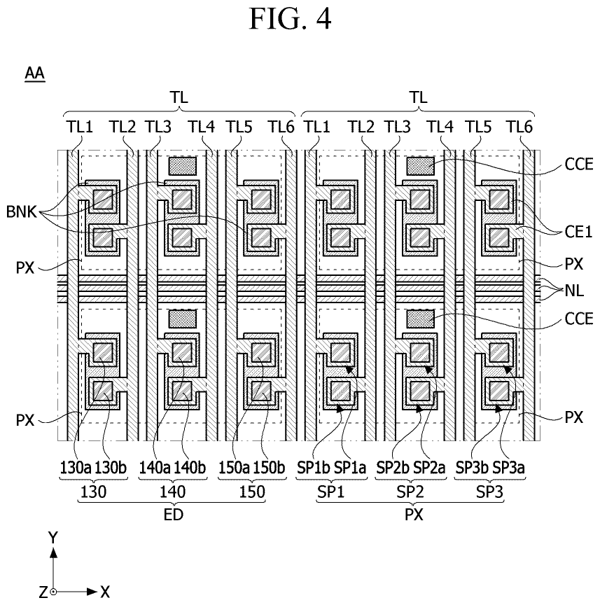

FIG. 1 is an exploded perspective view illustrating a display device according to one implementation of the present specification. FIG. 2 is a plan view of a display device according to one implementation of the present specification. FIG. 3 is a plan view of a display device according to one implementation of the present specification. FIG. 4 is an enlarged view of a display device according to one implementation of the present specification.

Referring to FIGS. 1 to 4, a display device 1000 according to one implementation of the present specification may include a display panel 100, a polarizing layer 293, an adhesive layer 295, a cover member 200, a support substrate 300, a flexible circuit board 400, and a printed circuit board 500.

For example, the display panel 100 of the display device 1000 may include a substrate 110. The substrate 110 may be a member that supports other components of the display device 1000. The substrate 110 may be made of an insulating material. For example, the substrate 110 may be made of glass, resin, or the like. Additionally, the substrate 110 may be made of a material having flexibility. For example, the substrate 110 may be made of a flexible plastic material such as polyimide (PI) or the like. However, the implementations of the present specification are not limited thereto.

The display panel 100 may implement information, video, and/or an image provided to a user. For example, the display panel 100 may include a display area AA and a non-display area NA. For example, the substrate 110 may include the display area AA and the non-display area NA. The display area AA and non-display area NA are not limited to being described only with respect to the substrate 110 but may be described throughout the entire display device 1000.

The display area AA may be an area in which an image is displayed. The display area AA may include a plurality of pixels PX. Each of the plurality of pixels PX may be composed of a plurality of sub-pixels. A plurality of micro-LEDs may be respectively arranged in the plurality of sub-pixels. The plurality of micro-LEDs may be configured differently depending on the type of display device 1000.

The non-display area NA may be an area in which no image is displayed. Various wires and circuits for driving the plurality of pixels PX of the display area AA may be positioned in the non-display area NA. For example, in the non-display area NA, various wires and driving circuits may be mounted, and a pad portion PAD to which an integrated circuit, a printed circuit, and the like are connected may be provided, but the implementations of the present specification are not limited thereto. For example, the driving circuit may be a data driving circuit and/or a gate driving circuit, but the implementations of the present specification are not limited thereto. Wires through which a control signal for controlling the driving circuits is supplied may be provided. For example, the control signal may include various timing signals including a clock signal, an input data enable signal, and synchronization signals, but the implementations of the present specification are not limited thereto. The control signal may be received through the pad portion PAD. For example, link wires LL for transmitting signals may be positioned in the non-display area NA. For example, the pad portion PAD may be connected to driving components such as the flexible circuit board 400 and the printed circuit board 500.

The non-display area NA may include a first non-display area NA1, a bending area BA, and a second non-display area NA2. For example, the first non-display area NA1 may be an area that surrounds at least a portion of the display area AA. The bending area BA may be an area extending from at least one of the plurality of sides of the first non-display area NA1, and may be a bendable area. The second non-display area NA2 may be an area extending from the bending area BA, and the pad portion PAD may be positioned in the second non-display area NA2. For example, the bending area BA may be in a bent state, and the remaining area of the substrate 110, excluding the bending area BA, may be in a flat state. In this case, as the bending area BA is in a bent state, the second non-display area NA2 may be positioned on the rear surface of the display area AA. However, the implementations of the present specification are not limited thereto.

The display area AA of the substrate 110 or the display device 1000 may be configured in various shapes depending on the design of the display device 1000. For example, the display area AA may be configured in a rectangular shape with four rounded corners, but the implementations of the present specification are not limited thereto. In another example, the display area AA may be configured in a rectangular shape with four right-angled corners, a circular shape, or the like, but the implementations of the present specification are not limited thereto.

According to the present specification, the width of the second non-display area NA2 in which a plurality of pad electrodes PE are arranged may be greater than the width of the bending area BA in which only the plurality of link wires LL are arranged. Additionally, the width of the display area AA in which the plurality of sub-pixels are arranged may be greater than the width of the bending area BA in which only the plurality of link wires LL are arranged. In the drawings, the width of the bending area BA is illustrated as being smaller than that of other areas of the substrate 110. However, the shape of the substrate 110 including the bending area BA is merely exemplary, and the implementations of the present specification are not limited thereto.

Referring to FIGS. 3 and 4, a plurality of pixel driving circuits PD may be arranged in the display area AA. The plurality of pixel driving circuits PD may be circuits for driving the micro-LEDs of the plurality of sub-pixels. Each of the plurality of pixel driving circuits PD may include a plurality of transistors including a driving transistor, a storage capacitor, and the like and may supply a control signal, power, and a driving current to the micro-LEDs of the plurality of sub-pixel to control the light emission operation of the plurality of micro-LEDs. For example, the pixel driving circuit PD may include a power wire and a signal wire for controlling the on/off state and/or light emission time of the micro-LED. For example, the plurality of pixel driving circuits PD may be a driving driver manufactured using a metal-oxide-silicon field effect transistor (MOSFET) fabrication process on a semiconductor substrate, but the implementations of the present specification are not limited thereto. The driving driver may include the plurality of pixel driving circuits PD and may drive the plurality of sub-pixels.

Referring to FIG. 1, the flexible circuit board 400 and the printed circuit board 500 may be positioned below the display panel 100. The flexible circuit board 400 and the printed circuit board 500 may be positioned on at least one edge of the display panel 100, but the implementations of the present specification are not limited thereto.

The pad portion PAD including the plurality of pad electrodes PE may be positioned in the second non-display area NA2. Driving components, including one or more flexible circuit boards (or flexible films) 400 and the printed circuit board 500, may be attached or bonded to the pad portion PAD. The plurality of pad electrodes PE of the pad portion PAD may be electrically connected to the one or more flexible circuit boards (or flexible films) 400, and may transmit various signals (or power) from the printed circuit board 500 and the flexible circuit board (or flexible film) 400 to the plurality of pixel driving circuits PD of display area AA.

The flexible circuit board (or flexible film) 400 may be a film in which various components are arranged on a base film having flexibility. For example, a driving IC, such as a gate driver IC or a data driver IC, may be positioned on the flexible circuit board (or flexible film) 400, but the implementations of the present specification are not limited thereto.

The printed circuit board 500 may include at least one hole 510, but the implementations of the present specification are not limited thereto. An internal component for sensing ambient light, temperature, or the like, which may be provided to a plurality of sensors, may be positioned in a region corresponding to the at least one hole 510. For example, the internal component may include an ambient light sensor (ALS), a temperature sensor, or the like, but the implementations of the present specification are not limited thereto. For example, the hole 510 may be a transmission hole or the like, but the implementations of the present specification are not limited thereto.

Referring to FIG. 1, the polarizing layer 293 may be positioned on the display panel 100. The polarizing layer 293 may prevent or reduce light generated from an external light source from entering the interior of the display panel 100 and affecting the micro-LEDs or the like.

The cover member 200 may be positioned on the polarizing layer 293. The cover member 200 may be a member for protecting the display panel 100. The adhesive layer 295 may be positioned between the polarizing layer 293 and the cover member 200. The cover member 200 may be attached to the display panel 100 by using the adhesive layer 295. The adhesive layer 295 may include an optically clear adhesive (OCA), an optically clear resin (OCR), a pressure sensitive adhesive (PSA), or the like, but the implementations of the present specification are not limited thereto.

The support substrate 300 may be positioned between the display panel 100 and the printed circuit board 500. The support substrate 300 may reinforce the rigidity of the display panel 100. The support substrate 300 may be a back plate, but the implementations of the present specification are not limited thereto.

Referring to FIGS. 1 to 4, the plurality of link wires LL may be arranged in the non-display area NA. The plurality of link wires LL may be wires for transmitting various signals from the one or more flexible circuit boards (or flexible films) 400 and the printed circuit board 500 to the display area AA. The plurality of link wires LL may extend from the plurality of pad electrodes PE of the second non-display area NA2 toward the bending area BA and the first non-display area NA1, and may be electrically connected to a plurality of driving wires VL of the display area AA.

The plurality of driving wires VL may be arranged in the display area AA and electrically connected to each of the plurality of pixel driving circuits PD.

As the bending area BA is bent, a portion of the plurality of link wires LL may also be bent together. Stress may be concentrated on a portion of the bent link wires LL, thereby causing cracks in the link wires LL. Accordingly, the plurality of link wires LL may be formed of a highly flexible conductive material to reduce cracks when the bending area BA is bent. For example, the plurality of link wires LL may be formed of a highly flexible conductive material, such as gold (Au), silver (Ag), or aluminum (Al), but the implementations of the present specification are not limited thereto. Additionally, the plurality of link wires LL may be formed of one of various conductive materials used in the display area AA. For example, the plurality of link wires LL may be made of one of molybdenum (Mo), chromium (Cr), titanium (Ti), nickel (Ni), neodymium (Nd), copper (Cu), silver (Ag) and magnesium (Mg), or an alloy thereof, but the implementations of the present specification are not limited thereto. The plurality of link wires LL may have a multilayer structure made of various conductive materials. For example, the plurality of link wires LL may have a triple-layer structure of titanium (Ti)/aluminum (Al)/titanium (Ti), but the implementations of the present specification are not limited thereto.

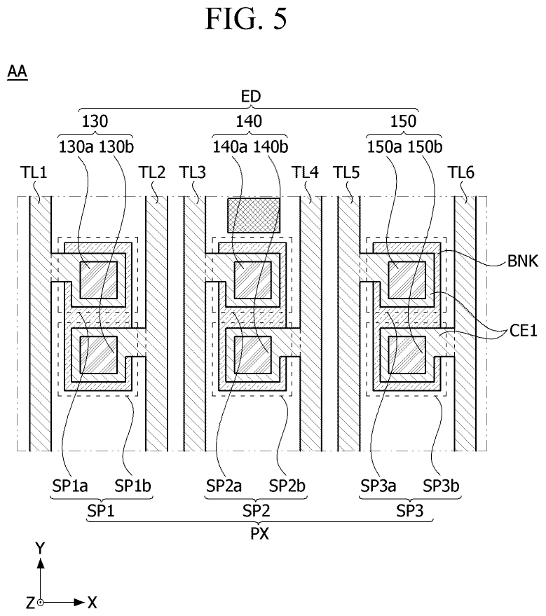

FIGS. 4 to 12 are plan views or cross-sectional views of a display device according to one implementation of the present specification. For example, FIG. 4 is an enlarged plan view of a display area including a plurality of pixels. For example, FIG. 5 is an enlarged plan view of a display area including one pixel.

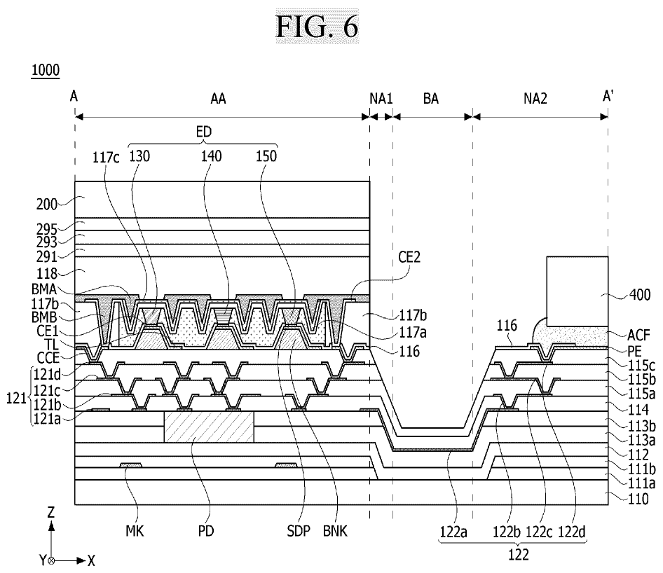

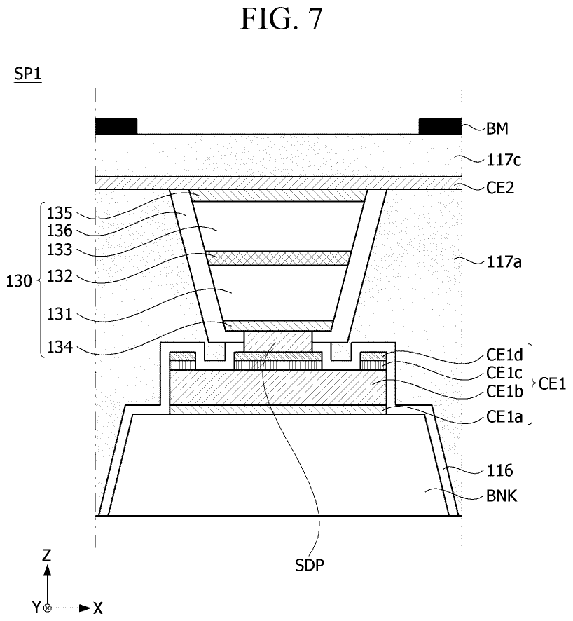

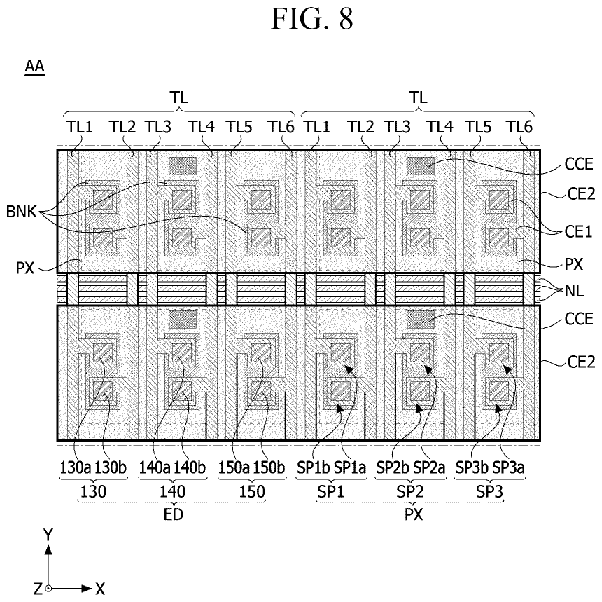

FIG. 6 is a cross-sectional view taken along line A-A′ in FIG. 3, and FIG. 7 is an enlarged cross-sectional view of a micro-LED region. Although FIGS. 4 and 5 only illustrate a plurality of signal wires TL, a plurality of communication wires NL, a plurality of first electrodes CE1, a plurality of contact electrodes CCE, a plurality of banks BNK, and a plurality of micro-LEDs ED, the implementations of the present specification are not limited thereto. FIG. 8 is a plan view illustrating a state in which a plurality of second electrodes CE2 are further provided in FIG. 4.

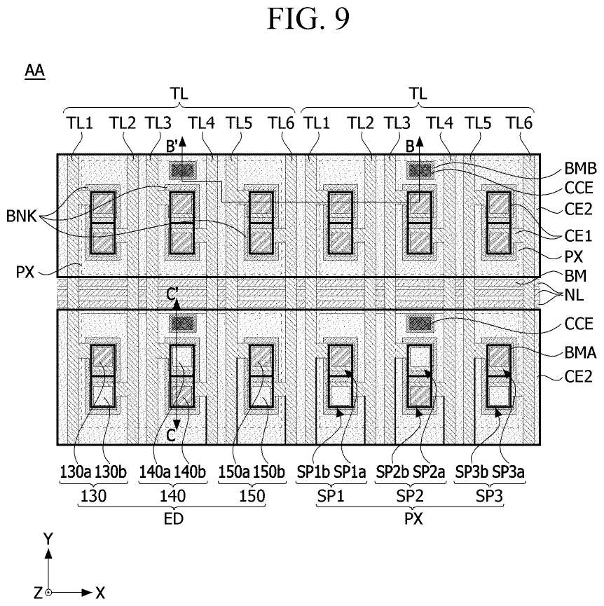

For example, FIG. 9 is a plan view illustrating a state in which a black matrix BM is further provided in FIG. 8.

Referring to FIGS. 4 and 5, the plurality of pixels PX composed of the plurality of sub-pixels may be arranged in the display area AA. Each of the plurality of sub-pixels may include the micro-LED ED and may emit light independently. The plurality of sub-pixels may be arranged in a matrix form including a plurality of rows and a plurality of columns, but the implementations of the present specification are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may be composed of a first-first sub-pixel SP1a and a first-second sub-pixel SP1b. The pair of second sub-pixels SP2 may be composed of a second-first sub-pixel SP2a and a second-second sub-pixel SP2b. The pair of third sub-pixels SP3 may be composed of a third-first sub-pixel SP3a and a third-second sub-pixel SP3b. For example, one pixel PX may include the first-first sub-pixel SP1a and the first-second sub-pixel SP1b, the second-first sub-pixel SP2a, the second-second sub-pixel SP2b, the third-first sub-pixel SP3a, and the third-second sub-pixel SP3b, but the implementations of the present specification are not limited thereto.

The plurality of sub-pixels constituting one pixel PX may be arranged in various ways. For example, in one pixel PX, the pair of first sub-pixels SP1 may be arranged in the same column, the pair of second sub-pixels SP2 may be arranged in the same column, and the pair of third sub-pixels SP3 may be arranged in the same column. The first sub-pixel SP1, the second sub-pixel SP2, and the third sub-pixel SP3 may be arranged in the same row. The number and arrangement of the plurality of sub-pixels constituting one pixel PX are merely exemplary, and the implementations of the present specification are not limited thereto.

The plurality of signal wires TL may be arranged in a region between the plurality of sub-pixels. The plurality of signal wires TL may extend in a column direction between the plurality of sub-pixels. The plurality of signal wires TL may be wires for transmitting an anode voltage from the pixel driving circuit PD to the plurality of sub-pixels. For example, the plurality of signal wires TL may be electrically connected to the plurality of pixel driving circuits PD and the first electrodes CE1 of the plurality of sub-pixels. The anode voltage outputted from the pixel driving circuit PD may be transmitted to the first electrodes CE1 of the plurality of sub-pixels through the plurality of signal wires TL. For example, the first electrode CE1 may be an electrode electrically connected to an anode electrode (134 in FIG. 7) of the micro-LED ED. Accordingly, the anode voltage from the signal wire TL may be transmitted to the anode electrode 134 of the micro-LED ED through the first electrode CE1.

Therefore, instead of forming a plurality of transistors and storage capacitors in the plurality of sub-pixels, the structure of the display device 1000 may be simplified by using the pixel driving circuit PD in which a plurality of pixel circuits are integrated. Additionally, as the circuits respectively positioned in the plurality of sub-pixels are integrated into one pixel driving circuit PD, high-efficiency and low-power operation may be achieved.

The plurality of signal wires TL may include a first signal wire TL1, a second signal wire TL2, a third signal wire TL3, a fourth signal wire TL4, a fifth signal wire TL5, and a sixth signal wire TL6. The first signal wire TL1 and the second signal wire TL2 may be electrically connected to the pair of first sub-pixels SP1, respectively. The third signal wire TL3 and the fourth signal wire TL4 may be electrically connected to the pair of second sub-pixels SP2, respectively. The fifth signal wire TL5 and the sixth signal wire TL6 may be electrically connected to the pair of third sub-pixels SP3, respectively.

The first signal wire TL1 may be positioned on one side of the pair of first sub-pixels SP1, and the second signal wire TL2 may be positioned on the other side of the pair of first sub-pixels SP1. The first signal wire TL1 may be electrically connected to the first electrode CE1 of one, e.g., the first-first sub-pixel SP1a, of the pair of first sub-pixels SP1. The second signal wire TL2 may be electrically connected to the first electrode CE1 of the other, e.g., the first-second sub-pixel SP1b, of the pair of first sub-pixels SP1.

The third signal wire TL3 may be positioned on one side of the pair of second sub-pixels SP2, and the fourth signal wire TL4 may be positioned on the other side of the pair of second sub-pixels SP2. For example, the third signal wire TL3 may be positioned adjacent to the second signal wire TL2. The third signal wire TL3 may be electrically connected to the first electrode CE1 of one, e.g., the second-first sub-pixel SP2a, of the pair of second sub-pixels SP2. The fourth signal wire TL4 may be electrically connected to the first electrode CE1 of the other, e.g., the second-second sub-pixel SP2b, of the pair of second sub-pixels SP2.

The fifth signal wire TL5 may be positioned on one side of the pair of third sub-pixels SP3, and the sixth signal wire TL6 may be positioned on the other side of the pair of third sub-pixels SP3. For example, the fifth signal wire TL5 may be positioned adjacent to the fourth signal wire TL4. The sixth signal wire TL6 may be positioned adjacent to the first signal wire TL1, which is connected to an adjacent pixel PX. The fifth signal wire TL5 may be electrically connected to the first electrode CE1 of one, e.g., the third-first sub-pixel SP3a, of the pair of third sub-pixels SP3. The sixth signal wire TL6 may be electrically connected to the first electrode CE1 of the other, e.g., the third-second sub-pixel SP3b, of the pair of third sub-pixels SP3.

The plurality of signal wires TL may be made of a conductive material. For example, the plurality of signal wires TL may be formed of a conductive material, such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO), but the implementations of the present specification are not limited thereto. In another example, the plurality of signal wires TL may have a multilayer structure of a conductive material. For example, the plurality of signal wires TL may have a multilayer structure of titanium (Ti)/aluminum (Al)/titanium (Ti)/indium tin oxide (ITO), but the implementations of the present specification are not limited thereto.

The plurality of communication wires NL may be arranged in a region between the plurality of pixels PX. The plurality of communication wires NL may extend in a row direction in the region between the plurality of pixels PX. The plurality of communication wires NL may be arranged in a region between the plurality of second electrodes (CE2 in FIG. 8), and may not overlap the plurality of second electrodes CE2. For example, the plurality of communication wires NL may be wires used for short-range communication, such as near field communication (NFC). The plurality of communication wires NL may function as an antenna. For example, the plurality of communication wires NL may be a plurality of connection wires or the like, but the implementations of the present specification are not limited thereto.

According to the present specification, the bank BNK may be positioned in each of the plurality of sub-pixels. The plurality of banks may be structures on which the plurality of micro-LEDs are mounted. The plurality of banks may guide the positions of the plurality of micro-LEDs ED in a transfer process for transferring the plurality of micro-LEDs ED to the display device 1000. During the transfer process of the plurality of micro-LEDs ED, the plurality of micro-LEDs ED may be transferred onto the plurality of banks BNK. The plurality of banks BNK may be bank patterns or structures, but implementations of present specification are not limited thereto.

The bank BNK of the first sub-pixel SP1, the bank BNK of the second sub-pixel SP2, and the bank BNK of the third sub-pixel SP3 may be spaced apart from each other. The bank BNK of the first sub-pixel SP1, the bank BNK of the second sub-pixel SP2, and the bank BNK of the third sub-pixel SP3 may be configured to be separated from each other. Accordingly, the banks BNK of the first sub-pixel SP1, the second sub-pixel SP2, and the third sub-pixel SP3, onto which different types of micro-LEDs ED are transferred, may be easily distinguished.

For example, the plurality of banks BNK may be formed of an organic insulating material. The plurality of banks BNK may be configured as a single layer or a multi-layer of the organic insulating material. For example, the plurality of banks BNK may be formed of a photoresist, polyimide (PI), or acryl-based material, but the implementations of present specification are not limited thereto.

The first electrode CE1 may be positioned in each of the plurality of sub-pixels. The first electrode CE1 may be positioned on the bank BNK. For example, the first electrodes CE1 may be positioned on the top and side surfaces of the plurality of banks BNK.

At least a portion of the first electrode CE1 may extend outside of the bank BNK and be electrically connected to the signal wire TL closest to the first electrode CE1. For example, a portion of the first electrode CE1 of the first-first sub-pixel SP1a may extend to one side region of the first-first sub-pixel SP1a and be electrically connected to the first signal wire TL1, and a portion of the first electrode CE1 of the first-second sub-pixel SP1b may extend to one side region of the first-second sub-pixel SP1b that is opposite to the one side region of the first-first sub-pixel SP1a and be electrically connected to the second signal wire TL2.

The first electrode CE1 may be electrically connected to the anode electrode 134 of the micro-LED ED, and may transmit the anode voltage from the pixel driving circuit PD to the micro-LED ED of each of the plurality of sub-pixels through the signal wire TL. Different voltages may be applied to the respective first electrodes CE1 of the plurality of sub-pixels according to an image to be displayed. For example, different voltages may be applied to the respective first electrodes CE1 of the plurality of sub-pixels. Accordingly, the first electrode CE1 may be a pixel electrode, and the implementations of the present specification are not limited thereto.

The plurality of micro-LEDs ED may include a first micro-LED 130, a second micro-LED 140, and a third micro-LED 150. The first micro-LED 130 may be positioned in the first sub-pixel SP1. The second micro-LED 140 may be positioned in the second sub-pixel SP2. The third micro-LED 150 may be positioned in the third sub-pixel SP3. For example, one of the first micro-LED 130, the second micro-LED 140, and the third micro-LED 150 may be a red micro-LED, another one may be a green micro-LED, and the remaining one may be a blue micro-LED, but the implementations of the present specification are not limited thereto. Accordingly, by combining red light, green light, and blue light emitted from the plurality of micro-LEDs ED, various colors of light including white may be implemented. The types of the plurality of micro-LEDs ED are merely exemplary, and the implementations of the present specification are not limited thereto.

Referring to FIGS. 8 and 9, the second electrode CE2 may be positioned in each of the plurality of sub-pixels. The second electrode CE2 may be positioned on the micro-LED ED. The second electrode CE2 may be electrically connected to the pixel driving circuit PD through the plurality of contact electrodes CCE.

For example, the second electrode CE2 may be electrically connected to a cathode electrode 135 of the micro-LED ED and may transmit a cathode voltage from the pixel driving circuit PD to the micro-LED ED. The same cathode voltage may be applied to the second electrode CE2 of each of the plurality of sub-pixels. For example, the same voltage may be applied to the second electrode CE2 of each of the plurality of sub-pixels and the cathode electrode 135 of the micro-LED ED. Accordingly, the second electrode CE2 may be a common electrode, but the implementations of the present specification are not limited thereto.

At least some of the plurality of sub-pixels may share the second electrode CE2. At least some of the second electrodes CE2 of the plurality of sub-pixels may be electrically connected to each other. As the same voltage is applied to the second electrodes CE2, the second electrodes CE2 of at least some sub-pixels may be shared. For example, the second electrodes CE2 of at least some of the plurality of pixels PX arranged in the same row may be connected to each other. For example, a single second electrode CE2 may be provided for the plurality of pixels PX. One second electrode CE2 may be provided for every n sub-pixels.

For example, some of the second electrodes CE2 of the plurality of sub-pixels may be spaced apart or separated from each other. For example, the second electrode CE2 connected to the pixels PX in an n^{th} row and the second electrode CE2 connected to the pixels PX in an (n+1)th row may be spaced apart or separated from each other. For example, the plurality of second electrodes CE2 may be spaced apart from each other with the plurality of communication wires NL, which extend in the row direction, interposed therebetween.

The plurality of second electrodes CE2 may be made of a transparent conductive material, but the implementations of the present specification are not limited thereto. The plurality of second electrodes CE2 may be made of a transparent conductive material, allowing light emitted from the micro-LED ED to be directed upward through the second electrode CE2. For example, the second electrode CE2 may be made of a transparent conductive material such as indium tin oxide (ITO), indium zinc oxide (IZO), or indium gallium zinc oxide (IGZO), but the implementations of the present specification are not limited thereto.

The plurality of contact electrodes CCE may be arranged on the substrate 110. For example, the plurality of contact electrodes CCE may be spaced apart from the plurality of banks BNK and the plurality of signal wires TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be positioned between the substrate 110 and the plurality of second electrodes CE2 and may transmit the cathode voltage from the pixel driving circuit PD to the second electrodes CE2.

For example, when using a micro-LED as the micro-LED ED, a plurality of micro-LEDs may be formed on a wafer and transferred to the substrate 110 of the display device 1000 to fabricate the display device 1000. In the process of transferring the plurality of micro-LEDs ED having a fine size from the wafer to the substrate 110, various defects may occur. For example, in some sub-pixels, a transfer failure may occur where the micro-LED ED is not transferred, and in some other sub-pixels, a defect may occur where the micro-LED ED is transferred to an incorrect position due to an alignment error. Additionally, even if the transfer process is normally performed, the transferred micro-LED ED itself may be defective. Therefore, in the transfer process of the plurality of micro-LEDs ED, in consideration of defects, a plurality of micro-LEDs ED that emit light of the same color may be transferred onto one sub-pixel. A lighting test may be performed on the plurality of micro-LEDs ED and only one micro-LED ED that is finally determined to be normal may be used.

For example, a first-first micro-LED 130a and a first-second micro-LED 130b may be transferred together onto one pixel PX, and their defect states may be inspected. If both the first-first micro-LED 130a and the first-second micro-LED 130b are determined to be normal, only the first-first micro-LED 130a may be used and the first-second micro-LED 130b may remain unused. In another example, if, among the first-first micro-LED 130a and the first-second micro-LED 130b, only the first-second micro-LED 130b is determined to be normal, the first-first micro-LED 130a may remain unused and only the first-second micro-LED 130b may be used. For example, referring to FIGS. 4, 5, 8, and 9, the 1-1 micro LED 130a and the 1-2 micro LED 130b may be applied as the 2-1 micro LED 140a and the 2-2 micro LED 140b, or the 1-1 micro LED 130a and the 1-2 micro LED 130b may be applied as the 3-1 micro LED 150a and the 3-2 micro LED 150b.

Accordingly, even if a plurality of micro-LEDs ED that emit light of the same color are transferred onto one pixel PX, ultimately, only one of the micro-LEDs ED may be used.

Thus, in a pair of micro-LEDs ED, one may be a main (or primary) micro-LED ED, while the other may be a redundancy micro-LED ED. The redundancy micro-LED ED may be an extra micro-LED ED that is transferred in preparation for a defect in the main micro-LED ED. The redundant micro-LED ED may be used as a replacement in the event of a failure of the main micro-LED ED. Thus, by transferring both the main micro-LED ED and the redundancy micro-LED ED to one pixel PX, degradation in display quality due to defects in the main micro-LED ED or the redundancy micro-LED ED may be minimized.

Ultimately, the black matrix BM may be formed in the display area AA and the non-display area NA, except for the emission area of the micro-LED, which is the redundancy micro-LED ED or the main micro-LED ED, used in each sub-pixel, to reduce light emitted from the unused micro-LED in each sub-pixel from being emitted upward.

The micro-LED may emit light in a top-emission manner, and light may be emitted from the top and side surfaces of the micro-LED. Light emitted from the side surface of the micro-LED may be mixed with light emitted from an adjacent micro-LED. To mitigate this, a first black matrix area BMA surrounding each micro-LED may be provided. The first black matrix area BMA surrounding the side surface of the micro-LED may be formed by forming a recess in a first optical layer positioned below the second electrode CE2, forming the second electrode CE2 along the recess, and positioning the black matrix BM inside the recess.

Two micro-LEDs, e.g., the main micro-LED and the redundancy micro-LED, may be positioned on a single bank BNK, the first black matrix area BMA may surround both the main micro-LED and the redundancy micro-LED, and may also be positioned between the main micro-LED and the redundancy micro-LED.

The first black matrix area BMA may be provided in each sub-pixel to be positioned between each communication wire NL and each signal wires TL, and may be positioned on each bank BNK to overlap each bank BNK.

In a region where the second electrode CE2 is connected to the plurality of contact electrodes CCE, a hole may be formed in a second optical layer 117b below the second electrode CE2 to allow the second electrode CE2 to be connected to the contact electrodes CCE. The second electrode CE2 may be connected to the contact electrode CCE through the hole, and a second black matrix area BMB, in which the black matrix is positioned inside the hole on the second electrode CE2, may be provided.

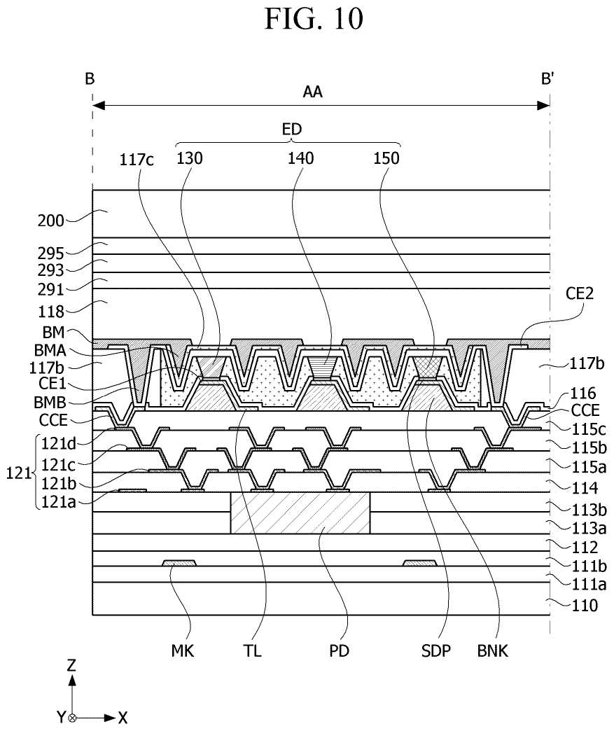

FIG. 6 is a cross-sectional view taken along line A-A′ in FIG. 3, and FIG. 10 is a cross-sectional view taken along line B-B′ in FIG. 9. For example, FIG. 6 is a cross-sectional view of the display area AA, the first non-display area NA1, the bending area BA, and the second non-display area NA2 according to one implementation of the present specification.

For ease of illustration, FIG. 6 depicts the A-A′ cutting line as not overlapping the driving wire VL and the link wire LL, but the A-A′ cutting line of FIG. 6 is intended to represent the same position as the adjacent driving wire VL and the link wire LL. FIG. 7 is an enlarged cross-sectional view of a portion of the micro-LED ED and the bank BNK in the first sub-pixel SP1.

Referring to FIGS. 6 and 10, a first buffer layer 111a and a second buffer layer 111b may be positioned in the remaining region of the substrate 110 excluding the bending area BA.

The first buffer layer 111a and the second buffer layer 111b may be positioned in the display area AA, the first non-display area NA1, and the second non-display area NA2. The first buffer layer 111a and the second buffer layer 111b may reduce the permeation of moisture or impurities through the substrate 110. The first buffer layer 111a and the second buffer layer 111b may be made of an inorganic insulating material. For example, the first buffer layer 111a and the second buffer layer 111b may be configured as a single layer or multi-layer of silicon oxide (SiOx) or silicon nitride (SiNx), but the implementations of the present specification are not limited thereto.

For example, a portion of the first buffer layer 111a and the second buffer layer 111b in the bending area BA may be removed. The top surface of the substrate 110 positioned in the bending area BA may be exposed from the first buffer layer 111a and the second buffer layer 111b. By removing the first buffer layer 111a and the second buffer layer 111b made of an inorganic insulating material from the bending area BA, cracks that may occur in the first buffer layer 111a and the second buffer layer 111b during bending may be minimized.

A plurality of alignment keys MK may be arranged between the first buffer layer 111a and the second buffer layer 111b. The plurality of alignment keys MK may be configured to identify the position of the pixel driving circuit PD during the fabricating process of the display device 1000. For example, the plurality of alignment keys MK may be configured to align the position of the pixel driving circuit PD transferred onto an adhesive layer 112. In another example, the plurality of alignment keys MK may be omitted.

The adhesive layer 112 may be positioned on the second buffer layer 111b. The adhesive layer 112 may be positioned in the display area AA, the first non-display area NA1, the bending area BA, and the second non-display area NA2. In another example, at least a portion of the adhesive layer 112 may be removed from the non-display area NA that includes the bending area BA. For example, the adhesive layer 112 may be made of any one of an adhesive polymer, epoxy resin, UV-curable resin, a polyimide-based material, an acrylate-based material, a urethane-based material, or polydimethylsiloxane (PDMS), but the implementations of the present specification are not limited thereto.

In the display area AA, the pixel driving circuit PD may be positioned on the adhesive layer 112. When the pixel driving circuit PD is implemented as a driving driver, the driving driver may be mounted on the adhesive layer 112 through a transfer process, but the implementations of the present specification are not limited thereto.

A first protective layer 113a and a second protective layer 113b may be positioned on the top or side surfaces of the adhesive layer 112 and the pixel driving circuit PD. The first protective layer 113a and the second protective layer 113b may be positioned to surround the side surface of the pixel driving circuit PD, but the implementations of the present specification are not limited thereto. For example, the second protective layer 113b may be positioned to cover at least a portion of the top surface of the pixel driving circuit PD.

For example, at least one of the first protective layer 113a and the second protective layer 113b positioned in the bending area BA may be omitted. For example, the first protective layer 113a may be entirely positioned over the display area AA and the non-display area NA, and the second protective layer 113b may be partially positioned over the display area AA, the first non-display area NA1, and the second non-display area NA2. For example, a portion of the second protective layer 113b in the bending area BA may be removed. However, the implementations of the present specification are not limited thereto.

The first protective layer 113a and the second protective layer 113b may be formed of an organic insulating material, but the implementations of the present specification are not limited thereto. For example, the first protective layer 113a and the second protective layer 113b may be formed of photoresist, polyimide (PI), or a photoacryl-based material, but the implementations of the present specification are not limited thereto. For example, the first protective layer 113a and the second protective layer 113b may be an overcoating layer or an insulating layer, but the implementations of the present specification are not limited thereto.

According to the present specification, a plurality of first connection wires 121 may be arranged on the second protective layer 113b in the display area AA. The plurality of first connection wires 121 may be wires for electrically connecting the pixel driving circuit PD to other components. For example, the pixel driving circuit PD may be electrically connected to the plurality of signal wires TL, the plurality of contact electrodes CCE, and the like through the plurality of first connection wires 121. For example, the plurality of first connection wires 121 may include a first-first connection wire 121a, a first-second connection wire 121b, a first-third connection wire 121c, and a first-fourth connection wire 121d, and the first-first connection wire 121a, the first-second connection wire 121b, the first-third connection wire 121c, and the first-fourth connection wire 121d may be electrically connected to each other through contact holes formed in insulating layers between the connection wires, but the implementations of the present specification are not limited thereto. Each of the plurality of first connection wires 121 refers to a signal wire positioned on the same layer, and the plurality of first connection wires 121 may include signal wires to which different signals are applied.

For example, a third protective layer 114 may be positioned on the second protective layer 113b. The third protective layer 114 may be entirely positioned over the display area AA and the non-display area NA. In the bending area BA, the third protective layer 114 may cover the side surface of the second protective layer 113b and the top surface of the first protective layer 113a. The third protective layer 114 may be made of an organic insulating material. For example, the third protective layer 114 may be made of photoresist, polyimide (PI), or a photoacryl-based material, but the implementations of the present specification are not limited thereto. For example, the first protective layer 113a, the second protective layer 113b, and the third protective layer 114 may be made of the same material, but the implementations of the present specification are not limited thereto.

The plurality of first-second connection wires 121b may be positioned on the third protective layer 114, and a first insulating layer 115a may be positioned on the plurality of first-second connection wires 121b. The first insulating layer 115a may be entirely positioned over the display area AA and the non-display area NA, but the implementations of the present specification are not limited thereto. The first insulating layer 115a may be made of an organic insulating material, but the implementations of the present specification are not limited thereto. For example, the first insulating layer 115a may be made of photoresist, polyimide (PI), or a photoacryl-based material, but the implementations of the present specification are not limited thereto.

The plurality of first-third connection wires 121c may be positioned on the first insulating layer 115a. The plurality of first-third connection wires 121c may be electrically connected to the plurality of first-second connection wires 121b. For example, the first-third connection wire 121c may be electrically connected to the first-second connection wire 121b through a contact hole of the first insulating layer 115a.

A second insulating layer 115b may be positioned on the plurality of first-third connection wires 121c. The second insulating layer 115b may be positioned in a region excluding the bending area BA, but the implementations of the present specification are not limited thereto. The second insulating layer 115b may be positioned in the display area AA, the first non-display area NA1, and the second non-display area NA2, but the implementations of the present specification are not limited thereto. For example, a portion of the second insulating layer 115b positioned in the bending area BA may be removed. The second insulating layer 115b may be made of an organic insulating material, but the implementations of the present specification are not limited thereto. For example, the second insulating layer 115b may be made of photoresist, polyimide (PI), or a photoacryl-based material, but the implementations of the present specification are not limited thereto.

The plurality of first-fourth connection wires 121d may be positioned on the second insulating layer 115b. The plurality of first-fourth connection wires 121d may be electrically connected to the plurality of first-third connection wires 121c. For example, the first-fourth connection wire 121d may be electrically connected to the first-third connection wire 121c through a contact hole of the second insulating layer 115b.

In the display area AA, the plurality of signal wires TL may be positioned on a third insulating layer 115c. The plurality of signal wires TL may be positioned to extend in a region between the plurality of banks BNK. For example, the plurality of signal wires TL may be positioned adjacent to any one of the plurality of banks BNK.

According to the present specification, a plurality of second connection wires 122 may be positioned on the second protective layer 113b in the non-display area NA. The plurality of second connection wires 122 may be wires for transmitting a signal, which has been transmitted to the pad portion PAD from the flexible circuit board (or flexible film) 400 and the printed circuit board 500 (see FIG. 1), to the pixel driving circuit PD of the display area AA. For example, the plurality of second connection wires 122 may be electrically connected to the plurality of pad electrodes PE to receive a signal from the flexible circuit board (or flexible film) 400 and the printed circuit board 500. And, the adhesive layer ACF may be disposed on a plurality of pad electrodes PE. The flexible circuit board (or flexible film) 400 may be disposed on the adhesive layer ACF. The flexible circuit board (or flexible film) 400 may be electrically connected to a plurality of pad electrodes PE through an adhesive layer ACF.

For example, the plurality of second connection wires 122 may extend from the pad portion PAD toward the display area AA to transmit a signal to the wire of the display area AA. In this case, the plurality of second connection wires 122 may function as the link wires LL. The plurality of second connection wires 122 may include a second-first connection wire 122a, a second-second connection wire 122b, a second-third connection wire 122c, and a second-fourth connection wire 122d. Thus, a signal from the flexible circuit board (or flexible film) 400 and the printed circuit board 500 may be transmitted to the second-first connection wire 122a through the second-fourth connection wire 122d, the second-third connection wire 122c, and the second-second connection wire 122b.

The plurality of first connection wires 121 and the plurality of second connection wires 122 may be formed of a highly flexible conductive material or any one of various conductive materials used in the display area AA.

For example, the plurality of first connection wires 121 and the plurality of second connection wires 122 may be made of one of molybdenum (Mo), chromium (Cr), titanium (Ti), nickel (Ni), neodymium (Nd), copper (Cu), silver (Ag) and magnesium (Mg), or an alloy thereof, but the implementations of the present specification are not limited thereto.

The third insulating layer 115c may be positioned on the plurality of first connection wires 121 and the plurality of second connection wires 122. The third insulating layer 115c may be positioned in a region excluding the bending area BA, but the implementations of the present specification are not limited thereto. The third insulating layer 115c may be positioned in the display area AA, the first non-display area NA1, and the second non-display area NA2. A portion of the third insulating layer 115c in the bending area BA may be removed. The third insulating layer 115c may be made of an organic insulating material, but the implementations of the present specification are not limited thereto. For example, the third insulating layer 115c may be made of photoresist, polyimide (PI), or a photoacryl-based material, but the implementations of the present specification are not limited thereto. In the display area AA, the plurality of banks BNK may be positioned on the third insulating layer 115c. The plurality of banks BNK may respectively overlap the plurality of sub-pixels. One or more micro-LEDs ED that emit light of the same color may be positioned above each of the plurality of banks BNK.

The plurality of contact electrodes CCE may be positioned on the third insulating layer 115c in the display area AA. The plurality of contact electrodes CCE may supply the cathode voltage from the pixel driving circuit PD to the second electrode CE2.

The first electrode CE1 may be positioned on the bank BNK. For example, the first electrode CE1 may extend from an adjacent signal wire TL toward the top of the bank BNK. The first electrode CE1 may be positioned on the top and side surfaces of the bank BNK. For example, the first electrode CE1 may extend from the signal wire TL on the top surface of the third insulating layer 115c to the side surface of the bank BNK and to the top surface of the bank BNK.

Referring to FIG. 7, the first electrode CE1 may be composed of a plurality of conductive layers. For example, the first electrode CE1 may include a first conductive layer CE1a, a second conductive layer CE1b, a third conductive layer CE1c, and a fourth conductive layer CE1d, but the implementations of the present specification are not limited thereto.

The first conductive layer CE1a may be positioned on the bank BNK. The second conductive layer CE1b may be positioned on the first conductive layer CE1a. The third conductive layer CE1c may be positioned on the second conductive layer CE1b. The fourth conductive layer CE1d may be positioned on the third conductive layer CE1c. For example, each of the first conductive layer CE1a, the second conductive layer CE1b, the third conductive layer CE1c, and the fourth conductive layer CE1d may be made of titanium (Ti), molybdenum (Mo), aluminum (Al), or titanium (Ti) and indium tin oxide (ITO), but the implementations of the present specification are not limited thereto.

According to the present specification, among the plurality of conductive layers constituting the first electrode CE1, some conductive layers with high reflection efficiency may be configured as an alignment key and/or a reflective plate for aligning the micro-LED ED.

For example, in order to configure the second conductive layer CE1b as a reflective plate, the third conductive layer CE1c and the fourth conductive layer CE1d covering the second conductive layer CE1b may be partially removed or etched. For example, portions of the third conductive layer CE1c and the fourth conductive layer CE1d positioned on the bank BNK may be removed or etched to expose the top surface of the second conductive layer CE1b. For example, in the third conductive layer CE1c and the fourth conductive layer CE1d, a central portion where the solder pattern SDP is positioned and a border portion (or edge portion) may be left, while the remaining portions may be removed. For example, the border portion (or edge portion) of each of the third conductive layer CE1c formed of titanium (Ti) and the fourth conductive layer CE1d formed of indium tin oxide (ITO) may not be etched. Accordingly, it is possible to prevent another conductive layer of the first electrode CE1 from being corroded by a tetramethylammonium hydroxide (TMAH) solution used in the masking process of the first electrode CE1.

According to the present specification, the first conductive layer CE1a and the third conductive layer CE1c may be made of titanium (Ti) or molybdenum (Mo). The second conductive layer CE1b may be made of aluminum (Al). The fourth conductive layer CE1d may include a transparent conductive oxide layer, such as indium tin oxide (ITO) or indium zinc oxide (IZO), which has good adhesion to the solder pattern SDP and exhibits corrosion resistance and acid resistance. However, the implementations of the present specification are not limited thereto.

According to the present specification, the signal wire TL, the contact electrode CCE, and the pad electrode PE positioned in the same layer as the first electrode CE1 may be composed of multiple layers of a conductive material, but the implementations of the present specification are not limited thereto.

According to the present specification, the solder pattern SDP may be positioned on the first electrode CE1 in each of the plurality of sub-pixels. The solder pattern SDP may bond the micro-LED ED to the first electrode CE1 to electrically connect the first electrode CE1 to the micro-LED ED. For example, the first electrode CE1 and the anode electrode 134 of the micro-LED ED may be electrically connected to each other through eutectic bonding using the solder pattern SDP, but the implementations of the present specification are not limited thereto. For example, when the solder pattern SDP be made of indium (In), and the anode electrode 134 of the micro-LED ED be made of gold (Au), the solder pattern SDP and the anode electrode 134 may be bonded by applying heat and pressure during the transfer process of the micro-LED ED. Through eutectic bonding, the micro-LED ED may be bonded to the solder pattern SDP and the first electrode CE1 without a separate adhesive material. For example, the solder pattern SDP may be made of indium (In), tin (Sn), or an alloy thereof, but the implementations of the present specification are not limited thereto. For example, the solder pattern SDP may be a bonding pad or a joining pad, but the implementations of the present specification are not limited thereto.

According to the present specification, a passivation layer 116 may be positioned on the plurality of signal wires TL, the plurality of first electrodes CE1, the plurality of contact electrodes CCE, and the third insulating layer 115c. For example, the passivation layer 116 may be positioned in the display area AA, the first non-display area NA1, and the second non-display area NA2. A portion of the passivation layer 116 positioned in the bending area BA may be removed. In the second non-display area NA2, a portion of the passivation layer 116 covering the plurality of pad electrodes PE may be removed. Since the passivation layer 116 is positioned to cover the remaining regions other than the bending area BA and the regions where the plurality of pad electrodes PE and the solder pattern SDP are positioned, penetration of moisture or impurities into the micro-LED ED may be reduced. For example, the passivation layer 116 may be composed of a single layer or multiple layers of silicon oxide (SiOx) or silicon nitride (SiNx), but the implementations of the present specification are not limited thereto.

In each of the plurality of sub-pixels, the micro-LED ED may be positioned on the solder pattern SDP. The first micro-LED 130 may be positioned in the first sub-pixel SP1. The second micro-LED 140 may be positioned in the second sub-pixel SP2. The third micro-LED 150 may be positioned in the third sub-pixel SP3.

The micro-LED ED may be formed on a silicon wafer using methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, but the implementations of the present specification are not limited thereto.

Referring to FIG. 7, the first micro-LED 130 may include the anode electrode 134, a first semiconductor layer 131, an active layer 132, a second semiconductor layer 133, the cathode electrode 135, and an encapsulation film 136, but the implementations of the present specification are not limited thereto. For example, the first micro-LED 130 may not include the encapsulation film 136.

For example, one of the first semiconductor layer 131 and the second semiconductor layer 133 may be implemented as a compound semiconductor of a group III-V or a group II-VI and may be doped with an impurity (or dopant). For example, one of the first semiconductor layer 131 and the second semiconductor layer 133 may be a semiconductor layer doped with an n-type impurity, while the other may be a semiconductor layer doped with a p-type impurity, but the implementations of the present specification are not limited thereto. For example, at least one of the first semiconductor layer 131 and the second semiconductor layer 133 may be a layer in which an n-type or p-type impurity is doped into a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), but the implementations of the present specification are not limited thereto.

The active layer 132 may be positioned between the first semiconductor layer 131 and the second semiconductor layer 133. The active layer 132 may emit light by receiving holes and electrons from the first semiconductor layer 131 and the second semiconductor layer 133. For example, the active layer 132 may be configured in one of a single well structure, a multi-well structure, a single quantum well structure, a multi-quantum well (MQW) structure, a quantum dot structure, and a quantum line structure, but the implementations of the present specification are not limited thereto. For example, the active layer 132 may be made of indium gallium nitride (InGaN) or gallium nitride (GaN), but the implementations of the present specification are not limited thereto.

The anode electrode 134 may be positioned below the first semiconductor layer 131. The anode electrode 134 may be formed of a conductive material capable of eutectic bonding with the solder pattern SDP. For example, the anode electrode 134 may be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the implementations of the present specification are not limited thereto.

The cathode electrode 135 may be positioned on the second semiconductor layer 133. For example, the cathode electrode 135 may electrically connect the second semiconductor layer 133 to the second electrode CE2. The cathode voltage outputted from the pixel driving circuit PD may be applied to the second semiconductor layer 133 through the contact electrode CCE, the second electrode CE2, and the cathode electrode 135. The cathode electrode 135 may be formed of a transparent conductive material such that light emitted from the micro-LED ED may be directed toward an upper side of the micro-LED ED, but the implementations of the present specification are not limited thereto. For example, the cathode electrode 135 may be formed of a material such as indium tin oxide (ITO), indium zinc oxide (IZO), or indium gallium zinc oxide (IGZO), but the implementations of the present specification are not limited thereto.

The encapsulation film 136 may be positioned on at least portions of the first semiconductor layer 131, the active layer 132, the second semiconductor layer 133, the anode electrode 134, and the cathode electrode 135. For example, the encapsulation film 136 may surround at least portions of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be positioned on the side surface of the first semiconductor layer 131, the side surface of the active layer 132, and the side surface of the second semiconductor layer 133. For example, the encapsulation film 136 may be formed of an insulating material such as silicon nitride (SiNx) or silicon oxide (SiOx), but the implementations of the present specification are not limited thereto.

According to implementations of the present specification, a first optical layer 117a may be positioned to surround the plurality of micro-LEDs ED in the display area AA. For example, the first optical layer 117a may be positioned to cover the plurality of micro-LEDs ED and the bank BNK in regions of the plurality of sub-pixels. For example, the first optical layer 117a may cover the bank BNK, a portion of the passivation layer 116 and the spaces between the plurality of micro-LEDs ED. The first optical layer 117a may be positioned between the plurality of banks BNK and between the plurality of micro-LEDs ED included in one pixel PX, or may cover those spaces. For example, the first optical layer 117a may extend in a second direction Y and may be separated in a first direction X. For example, the first optical layer 117a may be positioned between the passivation layer 116 and the second electrode CE2 to surround the side portions of the micro-LED ED and the bank BNK, but the implementations of the present specification are not limited thereto. For example, the first optical layer 117a may be a diffusion layer, a sidewall diffusion layer, or the like, but the implementations of the present specification are not limited thereto.

The first optical layer 117a may be formed of an organic insulating material in which fine particles are dispersed, but the implementations of the present specification are not limited thereto. For example, the first optical layer 117a may be made of siloxane in which fine metal particles such as titanium dioxide (TiO₂) particles are dispersed, but the implementations of the present specification are not limited thereto. Light from the plurality of micro-LEDs ED may be scattered by the fine particles dispersed in the first optical layer 117a and emitted to the outside of the display device 1000. Accordingly, the first optical layer 117a may improve the light extraction efficiency of the light emitted from the plurality of micro-LEDs ED.

For example, the first optical layer 117a may be positioned in each of the plurality of pixels PX, or may be commonly positioned in some of the pixels PX arranged in the same row, but the implementations of the present specification are not limited thereto. For example, the first optical layer 117a may be positioned in each of the plurality of pixels PX, or a single first optical layer 117a may be shared by the plurality of pixels PX. In another example, each of the plurality of sub-pixels may separately include the first optical layer 117a, but the implementations of the present specification are not limited thereto.

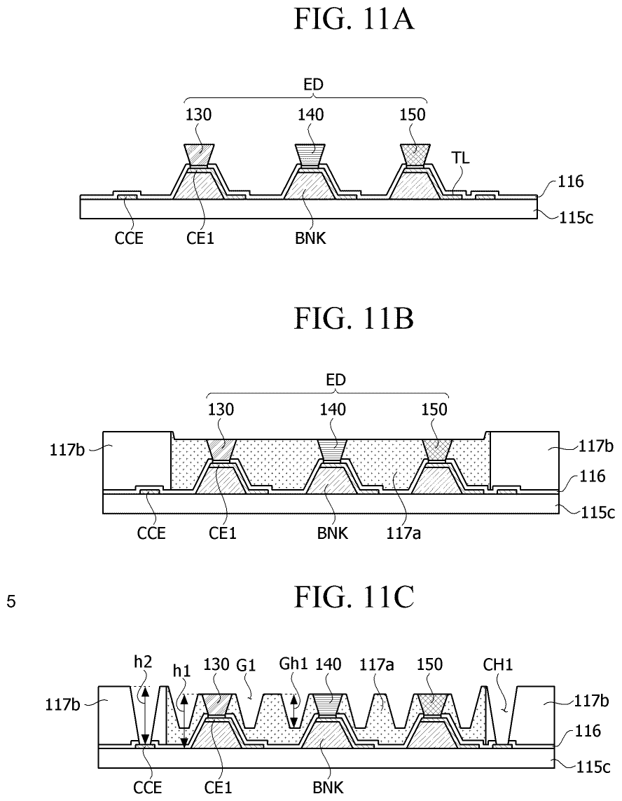

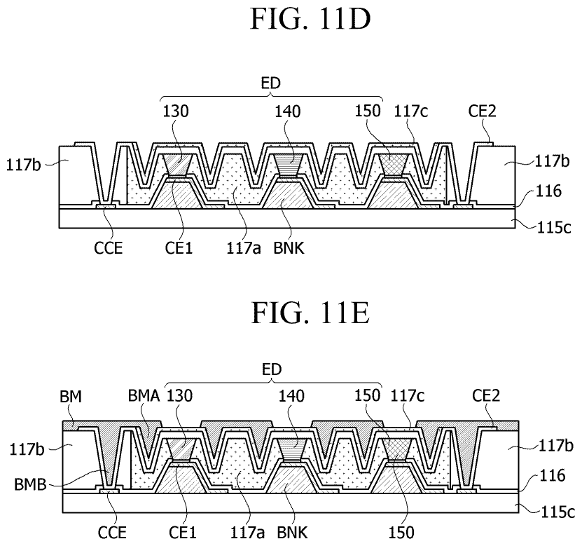

FIGS. 11A to 11E are schematic process diagrams illustrating a method of fabricating a display device according to one implementation of the present specification.

Referring to FIGS. 11A and 11B, after the micro-LED ED is positioned on the bank BNK, the first optical layer 117a may be positioned on the passivation layer 116 to cover the side portions and top surfaces of the bank BNK and the micro-LED ED. The cathode electrode 135 on the upper portion of the micro-LED ED may also be covered by the first optical layer 117a.

The second optical layer 117b may be positioned on the passivation layer 116 on which the first optical layer 117a is not positioned. For example, the second optical layer 117b may be positioned to surround the first optical layer 117a. For example, the second optical layer 117b may be in contact with the side surface of the first optical layer 117a. For example, the second optical layer 117b may be positioned in regions between the plurality of pixels PX. However, the implementations of the present specification are not limited thereto. For example, the second optical layer 117b may be a diffusion layer, a diffusion layer window, or a window diffusion layer, but the implementations of the present specification are not limited thereto.

The second optical layer 117b may be formed of an organic insulating material, but the implementations of the present specification are not limited thereto. The second optical layer 117b may be formed of the same material as the first optical layer 117a, but the implementations of the present specification are not limited thereto. For example, the first optical layer 117a may include fine particles and the second optical layer 117b may not include fine particles. For example, the second optical layer 117b may be made of siloxane, but the implementations of the present specification are not limited thereto.

The first optical layer 117a on the cathode electrode 135 of the micro-LED ED may be partially removed to expose the cathode electrode 135 (see FIG. 7) for subsequent connection with the second electrode CE2. Referring to FIG. 11C, a contact hole CH1 may be formed in the second optical layer 117b for the second electrode CE2 and the contact electrode CCE. At this time, a recess G1 may be formed between the respective micro-LEDs ED.

The recess G1 may be formed to surround each of the micro-LEDs ED on the plane. As a result, two or more recesses G1 may be formed between the micro-LEDs ED having different colors, but the implementations of the present specification are not limited thereto. For example, when the recess G1 is formed in a grid-shaped matrix pattern in the display area AA, only one recess G1 may be formed between the micro-LEDs ED having different colors.

On the plane, the recess G1 may be positioned above the bank BNK to overlap the bank BNK in each sub-pixel SP.

The recess G1 may be formed to be as close as possible to the micro-LED ED and to surround the micro-LED ED of each sub-pixel SP. One or more recesses G1 may be formed between the micro-LEDs ED within each sub-pixel SP, but the implementations of the present specification are not limited thereto.

The process may be performed through a photolithography process using a halftone mask. A halftone mask may be used in which different amounts of light exposure are applied to the top surface of the micro-LED ED, a region where the recess G1 is formed, and a region of the contact hole CH1. The first optical layer 117a of the recess G1 may be formed deeper than the first optical layer 117a on the top surface of the micro-LED ED, so that the cathode electrode 135 is exposed on the top surface of the micro-LED ED, and the recess G1 may have a first depth Gh1 greater than the height of the micro-LED ED. The first depth Gh1 may be smaller than a first length h1 from the bottom surface of the bank BNK to the top surface of the micro-LED ED.

When forming the contact hole CH1 in the second optical layer 117b, the second optical layer 117b and the passivation layer 116 may be partially removed to expose the top surface of the contact electrode CCE.

A second length h2 from the exposed top surface of the contact electrode CCE to the top surface of the second optical layer 117b may be greater than the first depth Gh1 of the recess G1.

Referring to FIG. 11D, the second electrode CE2 may be formed on top of the micro-LED ED, the first optical layer 117a and the second optical layer 117b, and inside the recess G1 and the contact hole CH1. The second electrode CE2 may be formed along the inner surface of the recess G1 and the contact hole CH1.

For example, the second electrode CE2 may be electrically connected to the plurality of contact electrodes CCE through the contact holes CH1 of the second optical layer 117b. The second electrode CE2 may be positioned on the plurality of micro-LEDs ED and electrically connected to the cathode electrodes 135. For example, the second electrode CE2 may be formed of a transparent conductive oxide such as indium tin oxide (ITO) or indium zinc oxide (IZO), but the implementations of the present specification are not limited thereto.

A third optical layer 117c may be positioned on the second electrode CE2. The third optical layer 117c may be positioned to overlap the plurality of micro-LEDs ED and the first optical layer 117a. Since the third optical layer 117c is positioned on the second electrode CE2 and above the plurality of micro-LEDs ED, it may improve the mura that may occur in some of the plurality of micro-LEDs ED. For example, when transferring the plurality of micro-LEDs ED onto the substrate 110 of the display device 1000, a region where a gap between the plurality of micro-LEDs ED is not uniform may occur due to process deviations or the like. If the gap between the plurality of micro-LEDs ED is not uniform, light exit regions of the respective micro-LEDs ED may also be arranged non-uniformly, and as a result, the mura may become visible to the user. Accordingly, by providing the third optical layer 117c configured to uniformly diffuse light above the plurality of micro-LEDs ED, it is possible to reduce the visual recognition of light emitted from some of the micro-LEDs ED appearing as the mura. Therefore, the light emitted from the plurality of micro-LEDs ED may be uniformly diffused by the third optical layer 117c and extracted to the outside of the display device 1000, thereby improving luminance uniformity of the display device 1000.

The third optical layer 117c may be formed of an organic insulating material in which fine particles are dispersed, but the implementations of the present specification are not limited thereto. For example, the third optical layer 117c may be formed of siloxane in which fine metal particles such as titanium dioxide (TiO₂) particles are dispersed, but the implementations of the present specification are not limited thereto. For example, the third optical layer 117c may be formed of the same material as the first optical layer 117a, but the implementations of the present specification are not limited thereto. For example, the third optical layer 117c may be a diffusion layer, a top surface diffusion layer, or the like, but the implementations of the present specification are not limited thereto.

Referring to FIG. 11E, the black matrix BM may be positioned on the second electrode CE2, the first optical layer 117a, the second optical layer 117b, and the third optical layer 117c in the display area AA. For example, the black matrix BM may fill the contact hole of the second optical layer 117b. The black matrix BM may be configured to cover the display area AA, and thus color mixing of light from the plurality of sub-pixels and external light reflection may be reduced. For example, the black matrix BM may also be positioned within the contact hole where the second electrode CE2 and contact electrode CCE are connected, thereby reducing light leakage between adjacent sub-pixels.

For example, the black matrix BM may be formed of an opaque material but the implementations of the present specification are not limited thereto. For example, the black matrix BM may be formed of an organic insulating material to which a black pigment or black dye has been added, but the implementations of the present specification are not limited thereto.

The black matrix BM may be formed to fill the inside of the recess G1. The first black matrix area BMA formed in the recess G1 and the second black matrix area BMB formed in the contact hole CH1 may completely fill the inside of the recess G1 and the contact hole CH1, respectively.

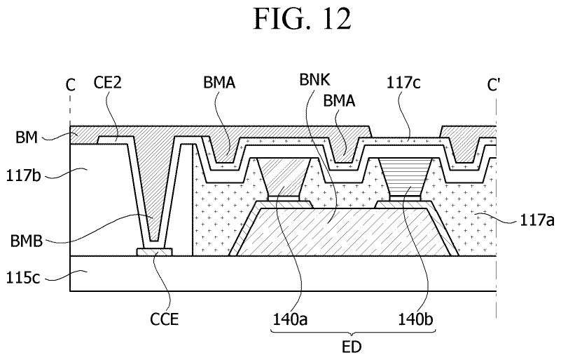

FIG. 12 is a cross-sectional view taken along line C-C′ in FIG. 9. Referring to FIG. 12, the recess G1 of the first optical layer 117a in one sub-pixel SP may surround two micro-LEDs ED positioned on a single bank BNK and may also be formed between the two micro-LEDs ED. For example, when a main micro-LED 140a exhibits abnormal operation, such as high brightness, flickering, or continuous light emission regardless of the signal, the sub-pixel may emit light using a redundancy micro-LED 140b. However, abnormal light emission of the main micro-LED 140a may be emitted through an upper BM opening, or light interfered with by the redundancy micro-LED 140b may be emitted.

In order to mitigate this, a recess may also be formed between the two micro-LEDs ED positioned on a single bank BNK, and the first black matrix area BMA may be provided within the recess, so that only normal light emission of each sub-pixel SP may be emitted.

A cover layer 118 (see FIG. 6) may be positioned on the black matrix BM in the display area AA. The cover layer 118 may protect the components below the cover layer 118. For example, the cover layer 118 may be formed of an organic insulating material, but the implementations of the present specification are not limited thereto. For example, the cover layer 118 may be made of photoresist, polyimide (PI), or a photoacryl-based material, but the implementations of the present specification are not limited thereto. For example, the cover layer 118 may be an overcoating layer, an insulating layer, or the like, but the implementations of the present specification are not limited thereto.

The polarizing layer 293 may be positioned on the cover layer 118 via a first adhesive layer 291 (FIG. 6). The cover member 200 (FIG. 6) may be positioned on the polarizing layer 293 via a second adhesive layer 295 (FIG. 6). For example, the first adhesive layer 291 and the second adhesive layer 295 may be formed of an optically clear adhesive (OCA), an optically clear resin (OCR), or a pressure sensitive adhesive (PSA), but the implementations of the present specification are not limited thereto.

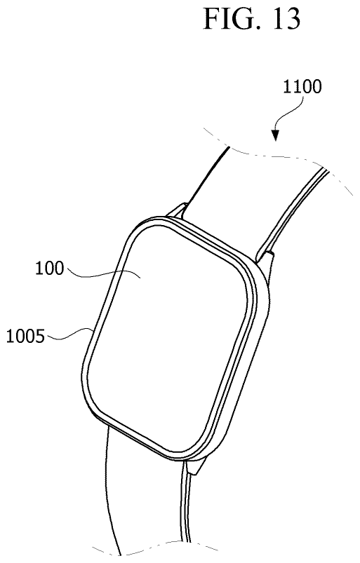

FIG. 13 illustrates an example of a device to which the display device according to implementations of the present specification is applied. According to FIG. 13, an electronic device may be included in a wearable device 1100. The display device 1000 according to implementations of the present specification may be applied to a mobile device, a laptop, a monitor, or a television, but the implementations of the present specification are not limited thereto.

Such an electronic device may include a case part 1005, and the display device 1000 including the display panel 100.

The display device according to various implementations of the present disclosure may be described as follows.

A display device according to various implementations of the present disclosure may comprise a substrate; a plurality of pixel driving circuits positioned on the substrate; a plurality of insulating layers positioned on the plurality of pixel driving circuits; a plurality of banks positioned on the plurality of insulating layers; a plurality of micro-LEDs positioned on the plurality of banks and respectively electrically connected to the plurality of pixel driving circuits; and a first optical layer positioned to surround the plurality of micro-LEDs and the plurality of banks, wherein the first optical layer includes at least one recess between the plurality of micro-LEDs.

According to one implementation of the present disclosure, t he display device may further comprise a second electrode positioned on a top surface of the first optical layer and in the at least one recess.

According to one implementation of the present disclosure, t he display device may further comprise a third optical layer positioned on the second electrode within the at least one recess and on the plurality of micro-LEDs.

According to one implementation of the present disclosure, t he display device may further comprise a second optical layer positioned on the plurality of insulating layers and surrounding the first optical layer.

According to one implementation of the present disclosure, the second optical layer may include a contact hole exposing a contact electrode positioned on the plurality of insulating layers.

According to one implementation of the present disclosure, a first depth of the recess may be smaller than a second length from a top surface of the contact electrode exposed through the contact hole to a top surface of the second optical layer.

According to one implementation of the present disclosure, t he display device may further comprise a black matrix positioned in a region of the display area other than emission areas of the respective sub-pixels.

According to one implementation of the present disclosure, the black matrix may include a first black matrix area positioned in the at least one recess.

According to one implementation of the present disclosure, the recess may be formed to surround each of the plurality of micro-LEDs.

According to one implementation of the present disclosure, two micro-LEDs may be positioned on one of the plurality of banks, the recess may be positioned to surround the two micro-LEDs on the plane, and the recess is further positioned between the two micro-LEDs.

According to one implementation of the present disclosure, at least two recesses may be positioned between micro-LEDs that emit light of different colors among the plurality of micro-LEDs.

According to one implementation of the present disclosure, a first length from a bottom surface of the bank to a top surface of the micro-LED may be greater than a first depth of the recess.

According to one implementation of the present disclosure, t he display device may comprise a substrate including a display area having a plurality of pixels and a non-display area; a pixel driving circuit positioned on the substrate; a plurality of insulating layers and a plurality of banks positioned on the pixel driving circuit; a plurality of micro-LEDs positioned on the plurality of banks and respectively electrically connected to the plurality of pixel driving circuits; and a first optical layer including a recess surrounding the plurality of micro-LEDs, wherein the recess at least partially overlaps the plurality of banks.

According to one implementation of the present disclosure, two micro-LEDs may be positioned on one of the plurality of banks, and the recess may be positioned to surround the two micro-LEDs on the plane, and is further positioned between the two micro-LEDs.

According to one implementation of the present disclosure, a first length from a bottom surface of the bank to a top surface of the micro-LED may be greater than a first depth of the recess.

According to one implementation of the present disclosure, t he display device may further comprise a second electrode positioned on a top surface of the first optical layer and in the recess.

According to one implementation of the present disclosure, t he display device may further comprise a black matrix positioned in the recess.

Although implementations of the present disclosure have been described in more detail with reference to the accompanying drawings, the present disclosure is not necessarily limited to the implementations, and various modifications may be carried out without departing from the technical spirit of the present disclosure.

Therefore, the implementations disclosed in the present disclosure are not intended to limited the technical spirit of the present disclosure, but intended to describe the same, and the scope of the technical spirit of the present disclosure is not limited by these implementations. Therefore, it should be understood that the above-described implementations are illustrative and not restrictive in all respects.

What is claimed is:

1. A display device comprising:
a substrate;
a plurality of pixel driving circuits positioned on the substrate;
a plurality of insulating layers positioned on the plurality of pixel driving circuits;
a plurality of banks positioned on the plurality of insulating layers;
a plurality of micro-LEDs positioned on the plurality of banks, wherein each micro-LED is electrically connected to a respective pixel driving circuit in the plurality of pixel driving circuits; and
a first optical layer positioned to surround the plurality of micro-LEDs and the plurality of banks,
wherein the first optical layer includes at least one recess between the plurality of micro-LEDs.

2. The display device of claim 1, further comprising:
a second electrode positioned on a top surface of the first optical layer and in the at least one recess.

3. The display device of claim 2, further comprising:
a third optical layer positioned on the second electrode within the at least one recess and on the plurality of micro-LEDs.

4. The display device of claim 1, further comprising:
a second optical layer positioned on the plurality of insulating layers and surrounding the first optical layer.

5. The display device of claim 4, wherein the second optical layer includes a contact hole exposing a contact electrode positioned on the plurality of insulating layers.

6. The display device of claim 5, wherein a first depth of the at least one recess is smaller than a second length from a top surface of the contact electrode exposed through the contact hole to a top surface of the second optical layer.

7. The display device of claim 4, further comprising:
a black matrix positioned in a region of the display area other than emission areas of the respective sub-pixels.

8. The display device of claim 7, wherein the black matrix includes a first black matrix area positioned in the at least one recess.

9. The display device of claim 1, wherein the recess is formed to surround each of the plurality of micro-LEDs.

10. The display device of claim 1, wherein two micro-LEDs are positioned on one of the plurality of banks, the recess is positioned to surround the two micro-LEDs on the plane, and the recess is further positioned between the two micro-LEDs.

11. The display device of claim 1, wherein at least two recesses are positioned between micro-LEDs that emit light of different colors among the plurality of micro-LEDs.

12. The display device of claim 1, wherein a first length from a bottom surface of the bank to a top surface of the micro-LED is greater than a first depth of the recess.

13. A display device comprising:
a substrate including a display area having a plurality of pixels and a non-display area;
a pixel driving circuit positioned on the substrate;
a plurality of insulating layers and a plurality of banks positioned on the pixel driving circuit;
a plurality of micro-LEDs positioned on the plurality of banks, wherein each micro-LED is electrically connected to a respective pixel driving circuit in the plurality of pixel driving circuits; and
a first optical layer including a recess surrounding the plurality of micro-LEDs,
wherein the recess at least partially overlaps the plurality of banks.

14. The display device of claim 13, wherein two micro-LEDs are positioned on one of the plurality of banks, and the recess is positioned to surround the two micro-LEDs on the plane, and is further positioned between the two micro-LEDs.

15. The display device of claim 13, wherein a first length from a bottom surface of the bank to a top surface of the micro-LED is greater than a first depth of the recess.

16. The display device of claim 13, further comprising:
a second electrode positioned on a top surface of the first optical layer and in the recess.

17. The display device of claim 13, further comprising:
a black matrix positioned in the recess.
